(19) United States
(12) Patent Application Publication
(10) Pub. No.: US 2006/0268629 A1
(43) Pub. Date: Nov. 30, 2006

(54) Reference voltage generator

(75) Inventors: Noureddine Senouci, St-Blaise/Neuchatel (CH); Alexander Heubi, La Chaux-de-Fonds (CH)

Correspondence Address: BIRCH STEWART KOLASCH & BIRCH, PO BOX 747, FALLS CHURCH, VA, 22040-0747, US

(73) Assignee: EMMA MIXED SIGNAL C.V., Amsterdam (NL)

(21) Appl. No.: 11/438,332

(22) Filed: May 23, 2006

(30) Foreign Application Priority Data
May 24, 2005 (EP) 05 405 358.2

(51) Int. Cl. G11C 5/14

(52) U.S. Cl. 365/189.09

(57) ABSTRACT

A reference voltage generator according to the invention includes a sub circuit (10) for producing a first current (6) with a negative thermal coefficient, a sub circuit (30) for producing a second current (4) with a positive thermal coefficient, a summing circuit (20) for summing these currents (4, 6) and an output circuit (40) for generating a reference voltage (1) that is stable over temperature, supply voltage and fabrication processes. The critical path between Vdd (2) and GND (3) that delimits the minimum possible supply voltage in the summing circuit (20) includes a mirror transistor (21, 22) and a cascode transistor (23, 24). Since the mirror transistors and the cascode transistors are designed for working in weak inversion their saturation voltage is about 0.15 V. Accordingly, the minimum possible supply voltage is the sum of the reference voltage and the saturation voltage a mirror transistor and a cascode transistor. With a reference voltage between 0.4 V and 0.7 V the reference voltage generator is operable with a minimum supply voltage between 0.7 V and 1 V.

### TECHNICAL FIELD

The invention relates to a device for generating a reference voltage, the device having a first circuit for generating a first temperature-depending current with a negative temperature coefficient, a second circuit for generating a second temperature-depending current with a positive temperature coefficient, an output circuit for generating said reference voltage and a summing circuit with a first mirror transistor for reproducing said first temperature-depending current, a second mirror transistor for reproducing said second temperature-depending current and means for summing said reproduced first and second temperature-depending currents. The invention further relates to device for generating a reference voltage, having an output circuit for generating said reference voltage, where said output circuit includes a resistive element and said reference voltage being a voltage across said resistive element. The invention also relates to an electrical device with such a device for generating a reference voltage.

### BACKGROUND ART

The continuous evolution in the design of integrated circuits, for example the evolution of the CMOS technology into deep submicron dimensions, allowes the design of chips with an increasing number of transistors, leading to chips and systems with an increasing number of functionalities. Often, such systems include both analog and digital circuits (mixed signal circuits) such as for example oscillators, voltage supervision or analog-to-digital and digital-to-analog converters. At the same time, the supply voltage of such systems has been decreased to 1.5 volt and even below in order to decrease the power consumption of these circuits.

Many of the mentioned functionalities require a stable reference signal such as for example a reference voltage so as to work properly. Typically, these reference voltages are generated by dedicated circuits that are powered by the systems power supply. One possibility to generate these reference voltages are the so called bandgap reference circuits, that produce a reference voltage that corresponds to the bandgap voltage of the used substrate material. In the most common case of silicon, this bandgap voltage is approximately 1.2 volt. The conventional bandgap reference circuits can therefore not be used anymore for generating the necessary reference voltage in systems with supply voltages of 1.5 volt and below.

In order to generate a reference current from a low supply voltage that is stable across a range of temperatures and input power supply voltages US 2003/0179608 A1 suggests a reference circuit that sums the currents of two current generation sub circuits which generate temperature dependent currents with an inverse temperature dependency. One of the current sub circuits includes two bipolar transistors (135, 136) and a resistor (139) and produces a current based on the difference of the base-to-emitter voltages of the two bipolar transistors. Since the current increases with an increasing operating temperature, the generated current has a positive thermal coefficient. The other sub circuit includes two NMOS transistors (115, 116) and a resistor (119). The current is produced based on the difference of the threshold voltages of the two NMOS transistors (115, 116) which are achieved by fabricating both NMOS transistors with different thicknesses of their oxide layers. Accordingly, this current has a negative thermal coefficient.

One of the problems with the suggested reference circuit is the fact that the generated current is highly process sensitive because the threshold voltage of the NMOS transistors and therewith the generated current depends on the thickness of the oxide layer of the NMOS transistors. Since the oxide layer thickness varies with the fabrication process, so does the generated current. A further disadvantage of this circuit is the fact, that at least one additional fabrication mask is necessary to produce transistors with different oxide layer thicknesses.

Another bandgap reference circuit is described in U.S. Pat. No. 6,366,071 B1. Again, a reference voltage is produced by summing two currents IPTVBE and IPTAT with opposite thermal coefficients and directing it through a resistor (RX).

The critical path between ground (GND) and the supply voltage (VCC) which determines the minimum supply voltage necessary for the circuit to work properly is the path in the IPTAT module (300) through transistor Q2 and resistor R1. The minimum supply voltage is the sum of the base-to-emitter voltage of the bipolar transistor Q2, the voltage drop across resistor R1 (which is equal to the difference ΔVBE between the base-to-emitter voltages of the bipolar transistors Q1 and Q2 as described in col. 3, equation 6), the drain-to-source voltage of an NMOS transistor and the threshold voltage of a PMOS transistor. This sum can not be lower than 1 volt which means that this reference circuit can not be operated with a supply voltage below 1 volt.

### SUMMARY OF THE INVENTION

It is the object of the invention to create a semiconductor bandgap reference circuit pertaining to the technical field initially mentioned, that is operable with a low supply voltage and that provides a reference voltage that is stable over a wide range of operating temperatures, a wide range of supply voltages and over different fabrication processes.

The solution of the invention is specified by the features of claim 1. According to the invention, the device for generating the reference voltage is built such that the critical path between ground and the supply voltage goes through the summing circuit which includes between its output and the supply voltage two mirror transistors connected in parallel that work in weak inversion region. The output of the summing circuit is the reference voltage. Accordingly, the supply voltage is equal to or higher than the sum of the reference voltage and the saturation voltage of one of the mirror transistors in the summing circuit. Since the mirror transistors are designed for working in weak inversion region, their saturation voltage is well below 0.2 V (volt).

Accordingly, if the reference voltage is chosen to be lower than 0.8 V, the reference circuit can 6be operated with a supply voltage below 1 V. Since the output current of the summing circuit is the sum of two temperature depending currents with opposite thermal coefficient, the output current and therefore also the reference voltage is stable over a wide range of operating temperatures. Furthermore, the temperature depending currents produced by the two circuits are not process sensitive such that the reference voltage is not sensitive to the fabrication process either.

A reference generator according to the invention is particularly useful in portable electronic devices that are powered by a battery. By designing such devices that are operable with supply voltages below 1 V, it is possible to reduce the power consumption and therewith to increase the operating time of these devices. Depending on the particular application, it is also possible to use different kinds of power sources, for example power supplies that are based on solar cells, that provide low supply voltages.

A possibility to produce a current with a negative thermal coefficient is based on the difference of the threshold voltages of two NMOS transistors such as described in the above mentioned US 2003/0179608 A1. Another possibility is based on the negative dependency of the base-to-emitter voltage of a bipolar transistor such as described in the above mentioned U.S. Pat. No. 6,366,071 B1.

In a preferred embodiment of the invention, the first circuit is designed such that the first temperature-depending current is proportional to a base-to-emitter voltage of a bipolar transistor which results in a temperature-depending current with a negative thermal coefficient. In order to work properly the voltage drops along the critical path of the first circuit has also to be equal to or lower than the supply voltage. For supply voltages below 1 V, this is achieved by implementing the bipolar transistor with a large emitter size. The larger the emitter size, the lower the base-to-emitter voltage of the bipolar transistor. In our case, the bipolar transistor is implemented such that its base-to-emitter voltage is decreased to be lower than 0.7 volt, for example to 0.6 V or even 0.5 V. A bipolar transistor with a large emitter size is advantageously implemented by means of a plurality of bipolar transistors that are connected in parallel.

A possibility to produce a current with a positive thermal coefficient is based on the difference of the base-to-emitter voltages of two bipolar transistors such as described in the above mentioned US 2003/0179608 A1 and U.S. Pat. No. 6,366,071 B1.

In another preferred embodiment of the invention, the second circuit for generating the second temperature depending current with a positive thermal coefficient includes a pair of transistors, particularly CMOS transistors, that are designed for working in weak inversion region. In weak inversion the drain current of CMOS transistors increases exponentially with the gate-to-source voltage which is similar to the current behaviour of bipolar transistors. Accordingly, the second temperature-depending current is proportional to the absolute temperature which means that it has a positive thermal coefficient.

As described above, the summing circuit includes a first and a second mirror transistor connected in parallel for reproducing the temperature depending currents. Directly summing these reproduced currents yields a bad PSRR (power supply rejection ratio). In a preferred embodiment of the invention, cascode transistors are added to the summing circuit such that the PSRR is improved. Particularly, at least one first cascode transistor is connected in series with the first mirror transistor and at least one second cascode transistor is connected in series with the second mirror transistor. Again, each cascode transistor is designed for working in weak inversion region such that their saturation voltage is well below 0.2 V. Therefore, the critical path between ground and the supply voltage now further includes said cascode transistors resulting in a minimum supply voltage that is equal to or higher than the sum of the reference voltage, the saturation voltage of a mirror transistor and the saturation voltage of each cascode transistor in series with that mirror transistor.

By adding only one cascode transistor in series with each mirror transistor, the resulting minimum supply voltage is the reference voltage plus twice the saturation voltage of a CMOS transistor in weak inversion which is typically below 0.2 V. By choosing a suitable reference voltage, preferably below 0.7 V and by correctly designing the transistors for saturation voltages of 0.15 V and below, the reference generation circuit can be operated with supply voltages down to 0.7 V or even 0.6 V.

For example, with transistors that have a saturation voltage in weak inversion about 0.15 V and with a reference voltage of about 0.5 V supply voltages down to 0.8 V are possible. If the saturation voltage of the transistors is lowered to for example 0.1 V and with a reference voltage of for example 0.4 V, supply voltages down to 0.6 V are possible.

While there exist several types of transistors, the mirror transistors and the cascode transistors are preferably CMOS field effect transistors.

While the summing circuit provides at its output a reference current which is the sum of the reproduced first and second temperature depending currents, it is desired to have a reference voltage at the output of the device. The reference voltage is generated by an output circuit that is connected to the summing circuit. The output circuit includes a resistive element where the reference current of the summing circuit is directed through thereby producing the reference voltage as a voltage across the resistive element.

Preferably, the resistive element is connected between the output of the summing circuit and ground such as to keep the supply voltage as low as possible. For filtering and stabilising the reference voltage, the output circuit further includes a capacitive element that is connected in parallel with the resistive element.

Generally, the output circuit provides a stable reference voltage at a fixed level. Accordingly, such a reference voltage generator has to be designed for a particular application and for specific environmental conditions.

It is a further object of the invention to create a reference circuit pertaining to the technical field initially mentioned, that enables a flexible and versatile usage of the reference circuit, for instance in different applications and environmental conditions.

The solution of this problem is specified by the features of claim 11. According to the invention, the output circuit of the device for generating the reference voltage is built for generating the reference voltage with at least two different levels. For selecting one of said at least two possible levels the device includes a voltage level selection circuit.

A stable reference voltage is for example needed in power management circuits of electrically powered devices, particularly in battery powered devices such as a hearing aid to determine whether the supply voltage is higher or lower than a shutdown reference voltage in order to safely shut down the device in case the battery dies. Having the possibility to choose one of several possible reference voltages allows to change the shutdown threshold of a corresponding power management circuit in dependency of different conditions such as the ambient temperature or the voltage level of the voltage source. Furthermore, different reference voltages enable a change of the frequency of the system clock, for example to realise a low power mode by changing a control voltage of an internal oscillator in response to a change of the reference voltage. The clock frequency f could for example depend on the oscillator's capacity C, the current I that charges the capacitor C and the reference voltage Vref according to the equation
f=(1/C)*(I/Vref).

While it is possible to manually choose one of the different possible reference voltages, it is also possible to add further means to automatically change the reference voltage in response to a change of the specified conditions. It would for example be possible to add a temperature sensor to monitor the ambient temperature together with a corresponding electrical circuit that automatically selects a suitable reference voltage.

Such an output circuit for generating a reference voltage with different levels and a corresponding voltage level selection circuit may be employed in any reference voltage generator such as for example the reference voltage generators known in the art and described in the documents mentioned in the chapter background art.

Such an output circuit for generating a reference voltage with different levels and a corresponding voltage level selection circuit may also be employed in a reference voltage generator as described hereinbefore. A device for generating a reference voltage including an output circuit for generating a reference voltage with different levels and a corresponding voltage level selection circuit is claimed in claims 8-10.

As outlined before, the reference voltage is generated by directing the reference current through a resistive element in the output circuit. That is the reference voltage corresponds to the voltage drop across that resistive element. Such an output circuit could for example be implemented by providing several, different resistors in parallel where only one of these resistors is actually connected to the output of the summing circuit.

In a preferred implementation of such an output circuit, the resistive element includes at least two resistive subelements that are connected in series, where the output circuit further includes at least one switching element, each switching element being connected in parallel with one of the resistive subelements. If the output circuit includes for example n (n being an integer larger than 1) resistive subelements such as normal resistors, the output circuit typically includes n−1 switching elements each connected in parallel to one resistive subelement. By switching a switching element ON, the corresponding resistor is bypassed such that no current flows through the resistor. Accordingly, there is no voltage drop across this bypassed resistor which means that the generated reference voltage is lower compared to the case where this particular switching element is OFF and the whole reference current is directed through the resistor.

Since there is no switching element connected across (at least) one of the resistive subelements, it is ensured that no short circuit is produced between the output of the summing circuit and ground.

While the switching elements could be realised by each kind of switch such as for example manual ON/OFF or toggle switches, it is preferred that at least one of the switching element includes a transistor, particularly a CMOS field effect transistor for bypassing the corresponding resistive subelement. By using transistors as switches, it is possible to control which of the resistive subelements are bypassed and which are not by means of control signals connected to the gates of the switching transistors. In an even more preferred embodiment of the invention, the device further includes controlling means for controlling said transistors. If the controlling means are programmable, the level of the generated reference voltage is programmable too which enables a user or the device to react on different circumstances in order to provide a reference voltage that best fits the current needs.

A reference voltage generator according to the invention can be used in every device that needs a reference voltage that is stable over temperature, supply voltage variations and different fabrication processes.

However, the invention enables the generation of a stable reference voltage from a supply voltage below 1 V. Hence, a reference voltage generator according to the invention is preferably used in an electrical device that includes a battery for providing the supply voltage. In battery powered devices it is particularly important to use circuits that are operable with supply voltages below 1 V in order to lower the power consumption and therewith to extend the operating time of the battery as much as possible.

This need is particularly true for listening devices such as for example hearing aids where the invention is advantageously applied.

Other advantageous embodiments and combinations of features come out from the detailed description below and the totality of the claims.

### BRIEF DESCRIPTION OF THE DRAWINGS

The drawings used to explain the embodiments show:

FIG. 1 A block diagram of a reference voltage generator according to the invention;

FIG. 2 a schematic circuit diagram of the reference voltage generator shown in FIG. 1;

FIG. 3 a schematic implementation of the bipolar transistor shown in FIG. 2;

FIG. 4 a diagram showing the supply voltage and the reference voltage in dependency of time;

FIG. 5a a diagram schematically showing both temperature-depending currents Iptat and Ivbe in dependency of the temperature;

FIG. 5b a diagram schematically showing the reference voltage in dependency of the temperature;

FIG. 6 a block diagram of another embodiment of the reference voltage generator according to the invention including a voltage level selection circuit according to a further aspect of the invention;

FIG. 7 an exemplary embodiment of the output circuit as shown in FIG. 6;

FIG. 8 an exemplary embodiment of a voltage level selection circuit as shown in FIG. 6 and

FIG. 9 another exemplary embodiment of an output circuit;

FIG. 10 a voltage supervision circuit including a reference voltage generator according to the invention.

In the figures, the same components are given the same reference symbols.

### PREFERRED EMBODIMENTS

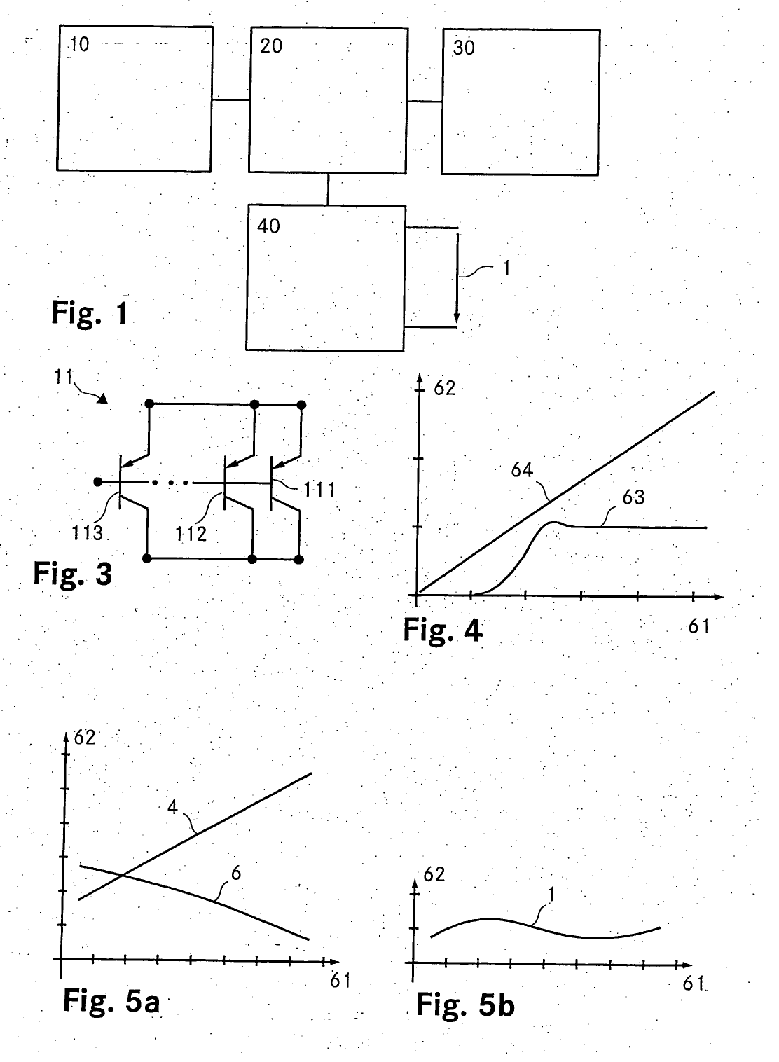

FIG. 1 shows a block diagram of a reference voltage generator according to the invention including a first sub circuit 10 for producing a first temperature depending current with a negative thermal coefficient, a second sub circuit 30 for producing a second temperature depending current with a positive thermal coefficient, a summing circuit 20 for generating a reference current that is the sum of the first and second temperature depending currents and an output circuit 40 that generates the stable reference voltage Vref 1.

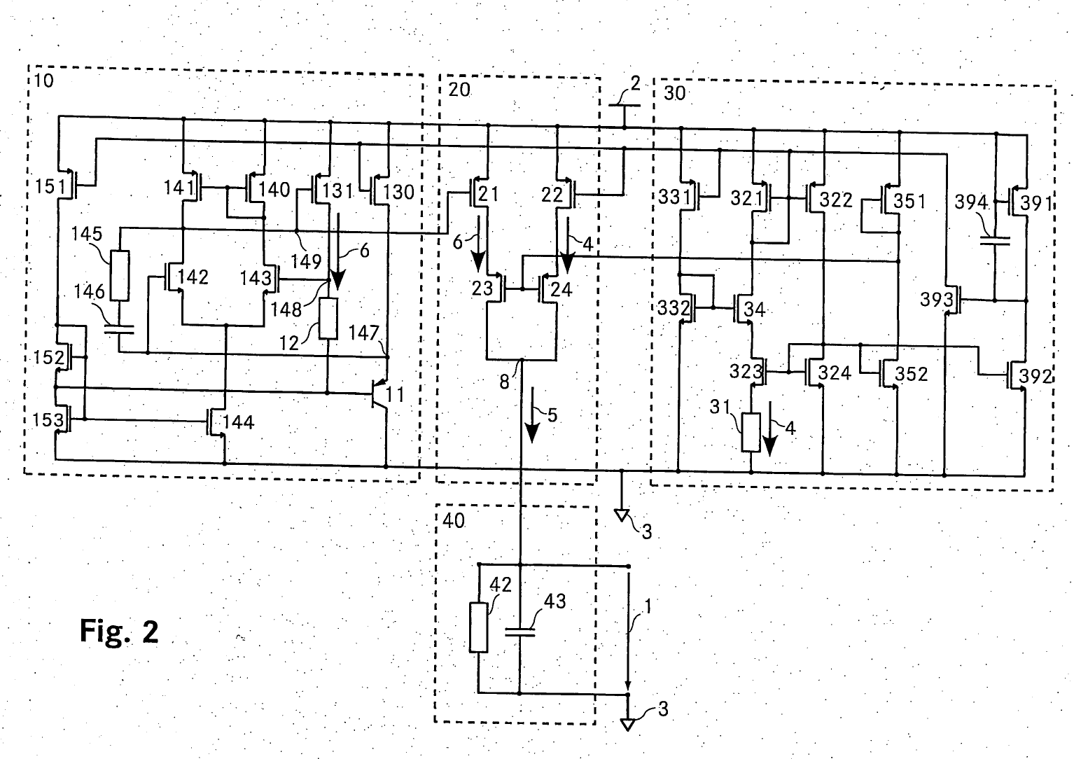

FIG. 2 shows a schematic circuit diagram of an exemplary embodiment of the reference voltage generator shown in FIG. 1.

The first sub circuit 10 includes a bipolar transistor 11. The collector of the bipolar transistor 11 is connected to ground GND 3, its emitter via node 147 to the drain of a PMOS transistor 130 the source of which is connected to the supply voltage Vdd 2. The base of bipolar transistor 11 is connected to a first terminal of a resistor Rvbe 12. The second terminal of Rvbe 12 is connected via node 148 to the drain of a further PMOS transistor 131 the source of which is connected to Vdd 2 as well. The sub circuit 10 further includes an OPAMP (operational amplifier) with the input nodes 147 and 148 and the output node 149 which is connected to the gate of PMOS transistor 131. The OPAMP includes transistors 140, 141, 142, 143 and 144 and the feedback circuit of resistor 145 and capacitor 146. Transistors 140 and 141 are PMOS transistors with their sources connected to Vdd 2 and their gates coupled together and connected to the drain of transistor 140. The drain of transistor 141 is connected to the output of the OPAMP, that is to the output node 149. The drain of transistors 140 and 141 are further coupled to the drain of NMOS transistors 143 and 142 respectively. The gates of transistors 142 and 143 are the input nodes 147 and 148 respectively. The sources of transistors 142 and 143 are coupled together and connected with the drain of NMOS transistor 144 the source of which is coupled to GND 3. The PMOS transistor 151 and the NMOS transistors 152 and 153 provide the bias voltages. The source of transistor 151 is connected to Vdd 2, its drain to the drain and the gate of transistor 152 as well as to the gates of transistors 153 and 144. The source of transistor 152 is connected to the drain of transistor 153 as well as to the first terminal of Rvbe 12 and the base of bipolar transistor 11 respectively. The source of transistor 153 is connected to GND 3.

Due to the presence of the OPAMP, the voltages at nodes 147 and 148 are equal. Accordingly, the base-to-emitter voltage Vbe of bipolar transistor 11 is equal to the voltage across Rvbe 12. The first temperature depending current Ivbe 6 flowing through Rvbe 12 is then defined as
Ivbe=Vbe/Rvbe. (I)

From (I) one can see that the temperature depending current Ivbe produced by sub circuit 10 is proportional to Vbe of the bipolar transistor 11 which means that is has a negative thermal coefficient.

In order to reduce the minimum supply voltage that is necessary for the sub circuit 10 to work properly, the voltage drops along the critical path between Vdd 2 and GND 3, that is through CMOS transistor 130 and bipolar transistor 11 have to be minimized. Accordingly, CMOS transistor 130 is sized and biased to work in weak inversion with a saturation voltage of about 0.15 V.

Regarding Vbe of bipolar transistor 11 it is to say that the current of a bipolar transistor is defined by:
Ic=As*Is*exp(Vbe/Ut) (II)
where Ic is the collector current through the bipolar transistor, As is the emitter size, Is is the saturation current and Ut is the thermal voltage (about 26 mV at room temperature). The base-to-emitter voltage Vbe is then:
Vbe=Ut*ln(Ic/(As*Is)) (III)

From (III) one can see that Vbe decreases with an increase of the emitter size As.

FIG. 3 shows an exemplary implementation of the bipolar transistor 11 with a large emitter size. In order to achieve a large emitter size, the bipolar transistor 11 is implemented as a plurality of single bipolar transistors 111, 112, . . . , 113 connected in parallel. By stacking for example up to forty bipolar transistors in parallel, Vbe can be reduced from about 0.8 V to about 0.5 V to 0.6 V.

Turning back to FIG. 2. The second sub circuit 30 includes a pair of PMOS transistors 321 and 322 and a pair of NMOS transistors 323 and 324. The gates of transistors 321 and 322 are coupled together and connected to the gate of transistors 151 and 130. Their sources are connected to Vdd 2 and while the drain of transistor 322 is directly connected to the drain and the gate of transistor 324, the drain of transistor 321 is coupled to the drain of transistor 323 via a cascode NMOS transistor 34. Cascode transistor 34 is provided to improve the PSRR. Two further transistors, PMOS transistor 331 and NMOS transistor 332 constitute the bias for cascode transistor 34. For this purpose, the source of transistor 331 is connected to Vdd 2, its gate to the drain and the gate of transistor 321 and its drain to the drain and the gate of transistor 332 as well as to the gate of cascode transistor 34.

The current Iptat 4 of sub circuit 30 is produced through a resistor Rptat 31, a first terminal of which is connected to the source of NMOS transistor 323 and a second terminal of which is connected to GND 3. The source of transistor 324 is also connected to GND 3.

The main idea of sub circuit 30 is to bias the transistors 323 and 324 in weak inversion region which results in an exponential current behaviour of the CMOS transistors 323 and 324 that is similar to that of a bipolar transistor. The transistor current can be expressed as
ID=ID0*exp(Vgs/Ut) (IV)
with
ID0=(W/L)*exp(−Vth/Ut) (V)
where Vgs is the gate-to-source voltage, W and L are the width and the length of the transistor channel and Vth is the threshold voltage of the transistor.

The current Iptat 4 through transistor 323 and Rptat can then be expressed as:
Iptat=(Ut/Rptat)*ln(A*B) (VI)
where A is the gain of the transistor pair 323/324 and B is the gain of the transistor pair 322/321.

From (VI) one can see that the temperature depending current Iptat produced by sub circuit 30 is proportional to the thermal voltage Ut which means that is has a positive thermal coefficient.

Sub circuit 30 further includes a start-up circuit to help the reference generator to find its correct operating point directly, when Vdd 2 rises from GND level to its final value. The start-up circuit includes PMOS transistor 391, NMOS transistors 392 and 393 and capacitor 394. The source of transistor 391 is coupled to Vdd 2 and its drain to the drain of transistor 392. The sources of transistors 392 and 393 are connected to GND 3. The drain of transistor 393 is coupled to the gates of transistors 321, 322 and 331. A first terminal of capacitor 394 is connected to Vdd 2 and the gate of transistor 391 and the second terminal is connected to the gate of transistor 393 as well as to the drains of transistors 391 and 392.

The summing circuit 20 includes two current sources, namely the PMOS mirror transistors 21 and 22. The sources of transistors 21 and 22 are connected to Vdd 2 and their gates to the gates of transistors 131 and 321 respectively in order to reproduce the temperature depending currents Ivbe 6 and Iptat 4 respectively. Two cascode PMOS transistors 23 and 24 are provided to improve the PSRR where the drains of the transistors 21 and 22 are connected to the sources of the cascode transistors 23 and 24 respectively. The drains of the cascode transistors 23 and 24 are coupled together at node 8 to add the two currents Ivbe 6 and Iptat 4 to form the reference current Iref 5. The bias for the cascode transistors 23 and 24 is provided by two transistors 351 and 352. The source of PMOS transistor 351 is connected to Vdd 2 and its gate and its drain are coupled together and connected to the drain of NMOS transistor 352. The gate of transistor 352 is connected to the gates of transistors 323, 324 and 392 and its source is connected to GND 3. The gates of the cascode transistors 23 and 24 are then coupled together and connected to the drains of the transistors 351 and 352.

The output circuit 40 includes a reference resistor Rref 42 that is connected between the output of the summing circuit at node 8 and GND 3. The output circuit further includes a capacitor 43. The reference voltage Vref 1 is generated across Rref 42, that is between node 8 and GND 3, by directing the reference current Iref 5 through reference resistor Rref 42.

Therefore, the reference voltage Vref 1 can be expressed as follows:

$$\begin{matrix}Vref = ( Ivbe + Iptat ) * Rref \\ = ( \frac{Vbe}{Rvbe} + \frac{Ut * ln ( A * B )}{Rptat} ) * Rref\end{matrix} \qquad ( VII )$$

For example, the values of the resistors and capacitors are as follows:
resistor Rptat 31: 111.3 k Ohm
resistor Rvbe 12: 890.4 k Ohm
resistor 145: 50 kOhm
capacitor 146: 0.750 pF
capacitor 394: 0.365 pF
capacitor 43: 5,5 pF

FIG. 4 shows a diagram of the supply voltage Vdd 64 and the reference voltage in volt (the y-axis 62 shows the range from 0 V to 1.5 V in steps of 0.5 V) in dependency of time (the x-axis 61 shows the range from 0 ms (milliseconds) to 2,5 ms in steps of 0.5 ms). At time 0 the device is switched ON. Line 64 shows the supply voltage Vdd which increases from 0 V to its final value. Line 63 shows the reference voltage that reaches its final value of 0.5 V after about 1.5 ms, that is when Vdd has reached only about 0.7 V.

FIG. 5a shows a diagram of the currents Iptat 4 and Ivbe 6 (the y-axis 62 shows the range from 150 nA to 450 nA (nanoampere) in steps of 50 nA) in dependency of the temperature (the x-axis 61 shows the range from −60° C. (degrees centigrade) to +100° C. in steps of 20° C.). One can see that the current Iptat 4 increases from about 230 nA at −50° C. to about 415 nA at +90° C. and that the current Ivbe 6 decreases from about 265 nA at −50° C. to about 175 nA at +90° C.

FIG. 5b shows the reference voltage Vref 1 (the y-axis 62 shows the range from 499 mV (millivolt) to 501 mV in steps of 1 mV) in dependency of the temperature (the x-axis 61 shows the range from −60° C. (degrees centigrade) to +100° C. in steps of 20° C.). One can see that the variation of the reference voltage 1 is of about 6.5 ppm/°C. (parts per million per degree centigrade) for the temperature range from −50° C. to +90° C.

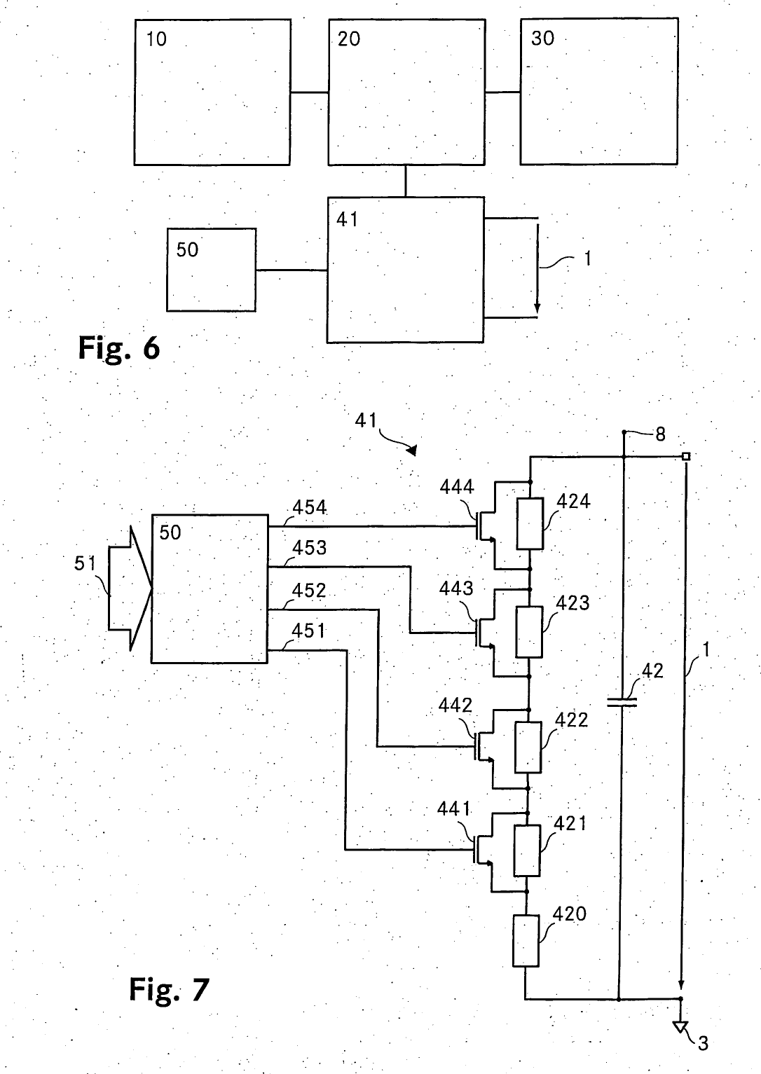

FIG. 6 shows a block diagram of another embodiment of the reference voltage generator according to the invention. In this embodiment, the output circuit 41 is built such that the reference voltages can be generated with several different levels. For selecting one of the possible levels, the reference voltage generator includes a voltage level selection circuit 50.

FIG. 7 shows an exemplary embodiment of the output circuit 41 of the reference voltage generator shown in FIG. 6. As described above in connection with FIG. 2, node 8 is the output of the summing circuit 20 delivering the reference current Iref 5. In this embodiment, the reference resistor Rref in the output circuit is replaced by a plurality of resistors 420, 421, 422, 423, 424 connected in series. Furthermore, a NMOS transistor 441, 442, 443, 444 is connected in parallel with each of the resistors 421, 422, 423 and 424 respectively such as to enable to bypass each of these resistors 421, 422, 423 and 424 by providing the gates of the transistors 441, 442, 443, 444 with a suitable control signal 451, 452, 453, 454. Depending on the level of the control signal at the gate of a transistor 441, 442, 443, 444, the corresponding resistors 421, 422, 423 and 424 are bypassed.

Accordingly, Rref can be expressed as
Rref=Rref_{—}0+β1*Rref_{—}1+β2*Rref_{—}2+. . .+βi*Rref_{—}i (VIII)
where the coefficients βj are either 1 or 0 depending on the corresponding control signal 451, 452, 453 or 454 and where the values Rref₁₃j correspond to the values of the resistors 420, 421, 422, 423, 424. This yields

$$\begin{matrix}Vref = ( \frac{Vbe}{Rvbe} + \frac{Ut * ln ( A * B )}{Rptat} ) * \\ ( Rref\_ 0 + β 1 * Rref\_ 1 + β 2 * Rref\_ 2 + K + β i * Rref\_i )\end{matrix} \qquad ( IX )$$

The values of the resistors 420, 421, 422, 423, 424 are for example 577 kOhm for resistor 420 and 76.92 kOhm for resistors 421, 422, 423 and 424.

For generating the control signals 451, 452, 453, 454 the reference voltage generator includes a voltage level selection circuit 50 which is built such that it generates different sets of control signals 451, 452, 453, 454 in order to generate different levels of the reference voltage Vref 1 by providing the voltage level selection circuit 50 with a suitable input code 51.

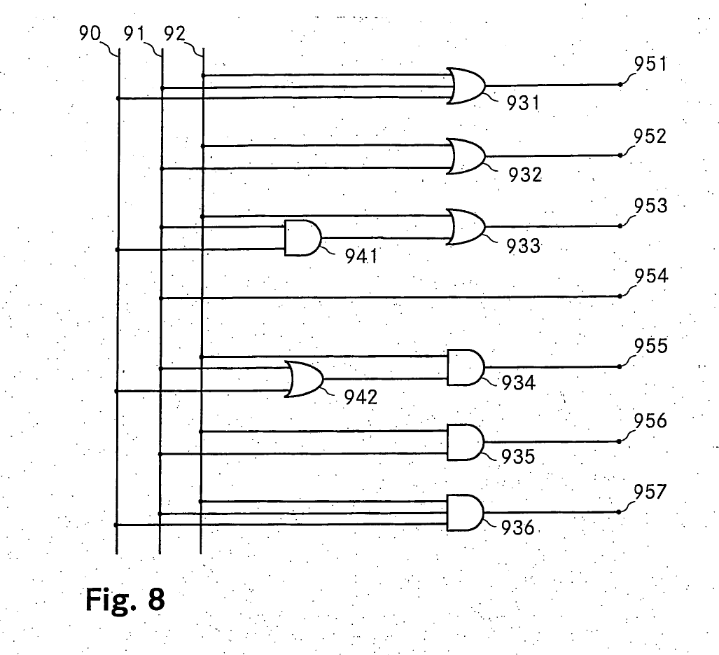

FIG. 8 shows a possible implementation of the voltage level selection circuit 50 forming a binary to thermometer decoder. In this example, the input code of the voltage level selection circuit 50 includes three bits 90, 91, 92 that enable to produce to 2³=8 different sets of seven control signals 951, 952, 953, 954, 955, 956, 957. With eight sets of control signals it is possible to generate eight different levels of the produced reference voltage 1 where the levels depend on the actual choice of the resistors Rref_j. The control signals form a so called thermometer code.

The following table shows the generated control signals in dependency of the three input bits 90,91 and 92.

| binary value | | | | | | | | | |
|---|---|---|---|---|---|---|---|---|---|
| of bit | | | levels of control signal | | | | | | |
| 92 | 91 | 90 | 951 | 952 | 953 | 954 | 955 | 956 | 957 |
| 0 | 0 | 0 | 0 | 0 | 0 | 0 | 0 | 0 | 0 |
| 0 | 0 | 1 | 1 | 0 | 0 | 0 | 0 | 0 | 0 |
| 0 | 1 | 0 | 1 | 1 | 0 | 0 | 0 | 0 | 0 |
| 0 | 1 | 1 | 1 | 1 | 1 | 0 | 0 | 0 | 0 |
| 1 | 0 | 0 | 1 | 1 | 1 | 1 | 0 | 0 | 0 |
| 1 | 0 | 1 | 1 | 1 | 1 | 1 | 1 | 0 | 0 |
| 1 | 1 | 0 | 1 | 1 | 1 | 1 | 1 | 1 | 0 |
| 1 | 1 | 1 | 1 | 1 | 1 | 1 | 1 | 1 | 1 |

A level of 1 of a control signal means that the control signal is high which switches the corresponding transistor ON and therewith bypasses the corresponding resistor Rref_j.

Instead of a binary to thermometer decoder it is also possible to use any other device that generates a suitable set of control signals from a given set of input signals. In case of binary input signals, any kind of decoder may be used that produces a set of control signals.

Another possibility to generate the control signals is to use a programmable memory, such as for example a ROM. The memory can be programmed to produce for each input of a set of binary inputs the desired set of output control signals. The values of the resistors Rref_j are then chosen to form the desired levels of the reference voltage 1.

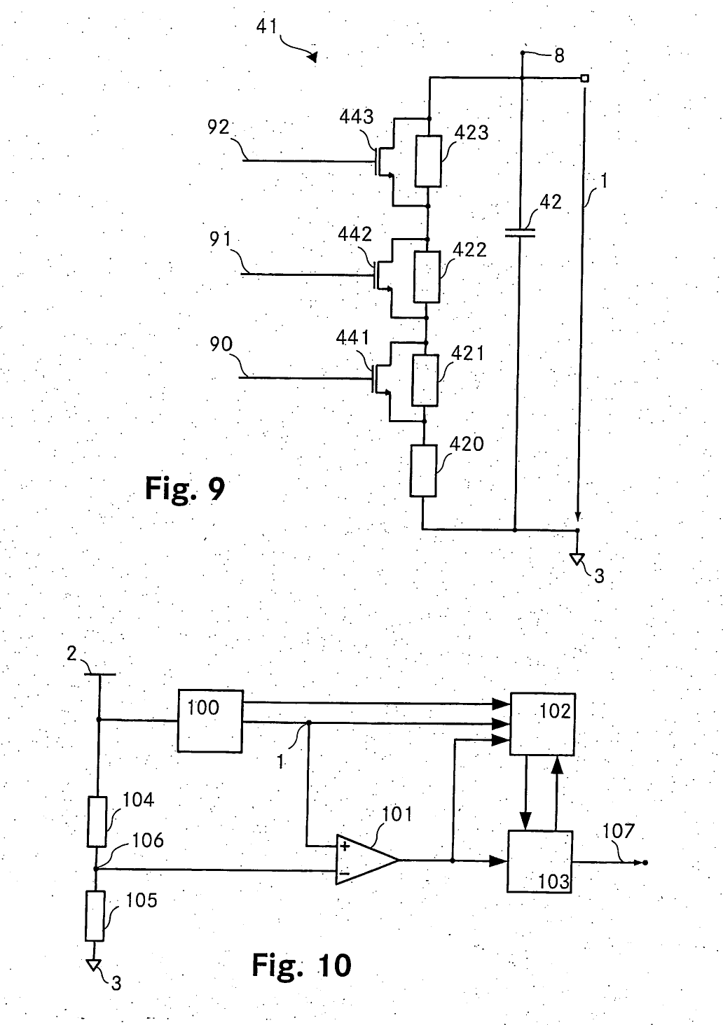

Instead of using the same resistor value for the resistors Rref_j, it is also possible to use different values to cover a range of desired voltages. FIG. 9 shows such an implementation with four resistors 420, 421, 422, and 423. In the example shown resistor 420 has the value Rref_{—}0, resistor 421 has the value ⅛* Rref_{—}1, resistor 422 has the value ¼*Rref_{—}1 and resistor 423 has the value ½*Rref_{—}1 where the values of Rref_{—}0 and Rref_{—}1 are different. In this case the minimum voltage step is defined by the minimum resistor value ⅛*Rref_{—}1 but it is also possible to have access to a big step of the reference voltage. In other words, the value of Rref_{—}1 can be chosen to fulfill the requirements of a specific implementation such that the minimim voltage step of the reference voltage that is necessary for a given implementation can be realised. In this case the binary code (bits 90, 91 and 92) can directly be used to select the desired level of the reference voltage by directly controlling the transistors 441, 442, 443. The following table shows the different selection codes (the different values of the bits 90, 91, 92) with the corresponding total values of the reference resistor Rref.

| binary value of bit | | | |
|---|---|---|---|
| 92 | 91 | 90 | total value of the reference resistor Rref |
| 0 | 0 | 0 | Rref_0 |
| 0 | 0 | 1 | Rref_0 + ⅛ * Rref_1 |
| 0 | 1 | 0 | Rref_0 + ¼ * Rref_1 |
| 0 | 1 | 1 | Rref_0 + ⅛ * Rref_1 + ¼ * Rref_1 |
| 1 | 0 | 0 | Rref_0 + ½ * Rref_1 |
| 1 | 0 | 1 | Rref_0 + ½ * Rref_1 + ⅛ * Rref_1 |
| 1 | 1 | 0 | Rref_0 + ½ * Rref_1 + ¼ * Rref_1 |
| 1 | 1 | 1 | Rref_0 + ½ * Rref_1 + ¼ * Rref_1 + |
| | | | ⅛ * Rref_1 |

Using a voltage level selection circuit 50 that decodes a binary input into the control signals allows the level of the reference voltage 1 to be programmable.

FIG. 10 shows a voltage supervision circuit, which is a typical application for a reference voltage generator 100 according to the invention. The supervision circuit is connected to an electrical device such as for example a listening device that is powered by a power supply that delivers a supply voltage Vdd 2. The supervision circuit monitors the supply voltage Vdd 2 and safely shuts down the electrical device in case the supply voltage Vdd 2 decreases to a predefined value or below.

In this application, the power supply delivers a voltage of 1.25 V and the reference voltage 1 generated by the reference voltage generator 100 is set to be 0.5 V. The voltage divider with the resistors 104 and 105 generates at node 106 a comparison voltage that depends on the level of the supply voltage Vdd 2. In the example shown, the values of the resistors 104 and 105 are chosen such that the comparison voltage falls below the reference voltage 1 of 0.5 V at the moment when the supply voltage Vdd falls below 0.83 V.

The comparator 101 compares the reference voltage 1 with the comparison voltage. Its output changes from high to low at the moment when the comparison voltage rises above the reference voltage 1. The output of the comparator 101 is fed to the input of an oscillator 102 as well as to the input of a timer 103. The oscillator 102 provides a clock signal for the timer 103 which in turn provides a reset signal 107 at its output. As long as the supply voltage Vdd 2 is lower than the predefined value of 0.83 V the reset signal 107 is high which means that the electrical device is resetted. At the moment when the comparison voltage increases above the reference voltage 1 the oscillator 102 starts to generate the clock signal and therefore the timer 103 starts to count. After a predefined delay, that is when the timer 103 reaches a predefined value, the reset signal 107 goes low which means that the electrical device is no longer resetted and can therefore start to work correctly.

If the supply voltage Vdd 2 falls below 0.83 V during operation of the electrical device (because for example the battery dies), The output of the comparator 101 changes to high and the oscillator 102 stops to produce the clock signal. The timer immediately produces a high reset signal which means that the electrical device is shut down safely.

In summary, it is to be noted that the invention enables reference voltage generators that generate a reference voltage that is stable over a wide range of operating temperatures, a wide range of supply voltages and over different fabrication processes that is operable with a supply voltage that is lower than 1 V. By properly sizing and biasing the transistors, the reference voltage generators according to the invention are operable with supply voltages down to 0.6 V.

1. Device for generating a reference voltage, the device having a first circuit for generating a first temperature-depending current with a negative temperature coefficient, a second circuit for generating a second temperature-depending current with a positive temperature coefficient, an output circuit for generating said reference voltage and a summing circuit with a first mirror transistor for reproducing said first temperature-depending currents, a second mirror transistor for reproducing said second temperature-depending current and means for summing said reproduced first and second temperature-depending currents, characterised in that said mirror transistors are designed for working in weak inversion region such that the device is operable with a supply voltage that is equal to or higher than a sum of the reference voltage and a saturation voltage of one of said mirror transistors where the reference voltage is lower than 0.8 V.

2. Device as claimed in claim 1, where said first temperature-depending current is proportional to a base-to-emitter voltage of a bipolar transistor having a large emitter size such that its base-to-emitter voltage is lower than 0.7 V, where said bipolar transistor is particularly implemented as a plurality of bipolar transistors connected in parallel.

3. Device as claimed in claim 1, where said second circuit includes a pair of transistors designed for working in weak inversion region such that the second temperature-depending current is proportional to an absolute temperature.

4. Device as claimed in claim 1, where the summing circuit includes at least one first cascode transistors connected in series with said first mirror transistor and at least one second cascode transistor connected in series with said second mirror transistor, said cascode transistors being designed for working in weak inversion region such that the device is operable with a supply voltage below one volt but equal to or higher than a sum of the reference voltage, a saturation voltage of one of said mirror transistors and a saturation voltage of the cascode transistor in series with the one of said mirror transistors.

5. Device as claimed in claim 4, where said mirror transistors and said cascode transistor are CMOS field effect transistors.

6. Device as claimed in claim 1, where said output circuit includes a resistive element, said reference voltage being a voltage across said resistive element.

7. Device as claimed in claim 6, where said resistive element is connected between an output of the summing circuit and ground, the output circuit including a capacitive element connected in parallel with said resistive element.

8. Device as claimed in claim 1, where the output circuit is built for generating said reference voltage with at least two different levels and the device further including a voltage level selection circuit for selecting one of said at least two levels.

9. Device as claimed in claim 8, where the resistive element includes at least two resistive subelements connected in series and where the output circuits includes at least one switching element, each of said at least one switching elements being connected in parallel with one of the at least two resistive subelements.

10. Device as claimed in claim 9, where said at least one switching element includes a transistor, particularly a CMOS field effect transistor, and the device further including controlling means for controlling said at least one transistor.

11. Device for generating a reference voltage, having an output circuit for generating said reference voltage, where said output circuit includes a resistive element and said reference voltage being a voltage across said resistive element, characterised in that the output circuit is built for generating said reference voltage with at least two different levels and in that the device includes a voltage level selection circuit for selecting one of said at least two possible levels.

12. Electrical device, particularly a listening device, including a battery for providing a supply voltage and a device for generating a reference voltage according to claim 1.

13. Device as claimed in claim 2, where the output circuit is built for generating said reference voltage with at least two different levels and the device further including a voltage level selection circuit for selecting one of said at least two levels.

14. Device as claimed in claim 3, where the output circuit is built for generating said reference voltage with at least two different levels and the device further including a voltage level selection circuit for selecting one of said at least two levels.

15. Device as claimed in claim 4, where the output circuit is built for generating said reference voltage with at least two different levels and the device further including a voltage level selection circuit for selecting one of said at least two levels.

16. Device as claimed in claim 5, where the output circuit is built for generating said reference voltage with at least two different levels and the device further including a voltage level selection circuit for selecting one of said at least two levels.

17. Device as claimed in claim 6, where the output circuit is built for generating said reference voltage with at least two different levels and the device further including a voltage level selection circuit for selecting one of said at least two levels.

18. Device as claimed in claim 7, where the output circuit is built for generating said reference voltage with at least two different levels and the device further including a voltage level selection circuit for selecting one of said at least two levels.

19. Electrical device, particularly a listening device, including a battery for providing a supply voltage and a device for generating a reference voltage according to claim 2.

20. Electrical device, particularly a listening device, including a battery for providing a supply voltage and a device a reference voltage according to claim 3.
